(19) United States
(12) Patent Application Publication
(10) Pub. No.: US 2026/0165089 A1
(43) Pub. Date: Jun. 11, 2026

(54) System and Method for Measuring Ion Currents During a Plasma Processing

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/974,819

(22) Filed: Dec. 10, 2024

(51) Int. Cl. H01L 21/66; G01R 19/00; H01L 21/683

(52) U.S. Cl. CPC H10P 74/203; G01R 19/0061; H10P 72/722

(57) ABSTRACT

Disclosed herein are a semiconductor manufacturing system and method for real time ion current measurement during plasma processing. The system features a control circuit with a thermal feedback loop and pulse-width modulation (PWM) for dynamic power regulation. Reductions in heating power required to sustain targeted temperatures, measured before and after plasma ignition, are used to determine ion currents based on data from previously conducted testing procedures.

### FIELD

The present invention relates to systems and methods for determining ion currents during plasma processing in semiconductor manufacturing. Specifically, it utilizes precise temperature control of electrostatic chucks (ESCs) and various testing procedures to infer ion currents based on heating power reductions before and after a plasma in a vacuum chamber is ignited, providing real time measurements with high accuracy and fast response.

### BACKGROUND

Ion currents are critical parameters in plasma-based semiconductor manufacturing processes, such as etching and deposition, where they directly influence process outcomes. Accurate, real time measurement of ion currents is important for monitoring plasma characteristics and optimizing process conditions. However, conventional techniques for ion current determination, such as Langmuir probes or Faraday cups, are often intrusive, difficult to implement in situ, or limited in their adaptability to varying operating conditions.

ESCs are indispensable in plasma processing, offering stable substrate positioning and precise temperature control. In many cases, the heating power required to maintain targeted ESC surface temperatures can provide indirect but accurate insights into ion currents. Yet, existing ESC temperature control systems typically rely on simple feedback loops or basic calibration methods that may not adapt effectively to changes in plasma operating conditions, targeted ESC surface and cold plate temperatures. These limitations hinder their applicability in ion current determination during dynamic processing environments.

The present invention introduces a novel system and method for determining ion currents by leveraging the advanced temperature control capabilities of ESCs. The invention incorporates a control circuit with a thermal feedback loop and pulse-width modulation (PWM) mechanism for precise heating power regulation. During a testing procedure, ion currents are measured under various operating conditions using established techniques, and the corresponding reductions in heating power for maintaining zonal ESC temperatures are recorded. This data is used to generate a lookup table or train a neural network, enabling real time inference of ion currents based on heating power reductions before and after a plasma is ignited.

This real time capability enhances process monitoring and control, ensuring uniformity and reliability in semiconductor manufacturing.

### SUMMARY

The present invention provides a novel system and method for determining ion currents during plasma processing in semiconductor manufacturing systems. By leveraging precise temperature control mechanisms for ESCs, the invention enables real time ion current determination based on reductions in heating power required to maintain targeted temperatures, before and after a plasma is ignited in a vacuum chamber.

In some embodiments, the system features a control circuit with a thermal feedback loop and pulse-width modulation (PWM) power delivery mechanism. Temperature sensors embedded in the ESC provide real time data, which the control circuit uses to dynamically adjust PWM duty cycles and achieve precise zonal temperature regulation. The system ensures fast response times.

The invention incorporates testing procedures to establish relationships between ion currents and heating power reductions under specific process conditions. In some implementations, one of the testing procedures involves operating the ESC at targeted temperatures and measuring ion currents using techniques such as Langmuir probes, Faraday cups, or electrode current monitoring. The testing procedure includes recording the reduced heating power in each ESC zone during plasma processing and correlating these reductions with ion currents under varying cold plate temperatures, zonal temperatures, and plasma conditions.

In one embodiment, a lookup table is generated from the data generated from the testing procedures to map heating power reductions to ion currents for specific operating conditions. In other implementations, a neural network is trained using the data to dynamically infer ion currents during processing. These methods provide the flexibility to handle complex thermal interactions and variability in plasma operating conditions.

During operation, the system controller uses the lookup table or neural network to infer ion currents in real time. By monitoring the heating power reductions for each zone, the system determines ion currents accurately and reliably, enabling enhanced process control.

This invention offers a robust solution for determining ion currents, ensuring precise measurements. The system is applicable across a range of plasma processing operations, contributing to improved uniformity and performance in semiconductor manufacturing processes.

### BRIEF DESCRIPTIONS OF THE DRAWINGS

The clarity of the embodiments is enhanced by referring to the following description in conjunction with the accompanying drawings:

FIG. 1A: Illustrates an exemplary process system, including a temperature control system including an ESC.

FIG. 1B: Provides a schematic functional block diagram of a heating unit configured to regulate the temperature of a specific zone on the ESC.

FIG. 2A: Demonstrates a first implementation of an ESC, showing the ESC divided into three concentric zones, each independently controlled for distinct temperature regulation.

FIG. 2B: Showcases a second implementation of an ESC, where the ESC is configured with a grid of independently controlled zones to achieve precise temperature control across the surface.

FIG. 3: Highlights a schematic diagram of the control circuits for the ESC temperature control system, incorporating a thermal feedback loop to dynamically adjust zonal temperatures.

FIG. 4A: Presents a flowchart detailing a first testing procedure for calibrating the ESC and determining reference voltages for the control circuits under varying conditions.

FIG. 4B: Showcases a flowchart of the method for temperature control across the zonal ESC, illustrating the use of the data generated from the first testing procedure to maintain precise temperatures during operation.

FIG. 5A: Presents a flowchart detailing a process using a second and a third testing procedure for correlating the ions current to the plasma conditions.

FIG. 5B: Showcases a flowchart of the method for determining in real ion currents during a plasma processing by leveraging a look up table or a neural network.

### DETAILED DESCRIPTIONS

To foster a comprehensive understanding, this description elaborates on specific implementations of the current invention. While specific details are provided for elucidation, adjustments and variations that align with the following claims are deemed acceptable. Some established procedures and components are selectively detailed to underscore the unique facets of the invention.

### Definition

Electrostatic Chuck (ESC): A device used in semiconductor manufacturing to securely hold a substrate, such as a semiconductor wafer, during processing by electrostatic forces, while also enabling precise thermal control of the substrate.
Process Chamber: A vacuum chamber where plasma-based semiconductor processes, such as etching or deposition, are performed, often including components like ESCs and plasma sources.
Zonal Temperature Control: A method of independently controlling the temperature of distinct regions (zones) on the ESC surface to achieve uniform or customized thermal conditions across the substrate, critical for maintaining process consistency.
Thermal Feedback Loop: A control mechanism that dynamically adjusts heating power in real time based on temperature sensor data and a reference voltage to maintain a target temperature.
Pulse-Width Modulation (PWM): A technique used to regulate power delivery to heaters by modulating the duty cycle of electrical pulses, allowing precise control of the heater's energy input.
Calibration Procedure: A pre-processing step to determine reference voltages or other parameters for temperature control and ion current determination, involving ESC surface temperature and heating power testing under various operating conditions.
Lookup Table: A data structure generated during testing procedures, correlating parameters such as target ESC temperatures, cold plate temperatures, heating power reductions, and ion currents to enable real time system control.
Neural Network: A machine learning model trained using data generated during testing procedures to dynamically infer ion currents or reference voltages based on real time measurements.
Cold Plate: A cooling mechanism integrated with the ESC, utilizing internal coolant channels to regulate the base temperature of the ESC, ensuring stable thermal conditions during operation.
Heating Unit: A localized heating mechanism embedded within the ESC for zonal temperature control, typically including a heater, temperature sensor, and control circuit.
Temperature Sensor: A device embedded in the ESC or cold plate, such as a diode, transistor, or resistor, used to measure temperature in real time and provide data for feedback control.
Control Circuit: An electronic system that utilizes data generated from temperature sensors, adjusts PWM duty cycles, and ensures precise and stable temperature control of the ESC zones.
Reference Voltage: A target voltage value used in the control circuit's thermal feedback loop to maintain the ESC at a specified temperature.
Ion Current Measurement: The process of quantifying the ion flux within the process chamber, which is indirectly determined in this invention by correlating heating power reductions before and after a plasma is ignited with calibrated ion current data.
Plasma Ion Flux: The flow of ions generated in the plasma process chamber, which can transfer energy to the surface of a substrate hold by the ESC, affecting its thermal balance and heating power requirements.
Heating Power Reduction: The decrease in power delivered to the ESC heaters to maintain a targeted temperature when plasma ion flux contributes additional heating.
Plasma Source: A component of the process system that generates and sustains the plasma, whose operating conditions influence ion current and thermal effects on the ESC.
Bias Unit: A component that applies an electrical bias to the ESC or substrate, affecting the ion energy and flux in the process chamber, critical for processes such as etching.

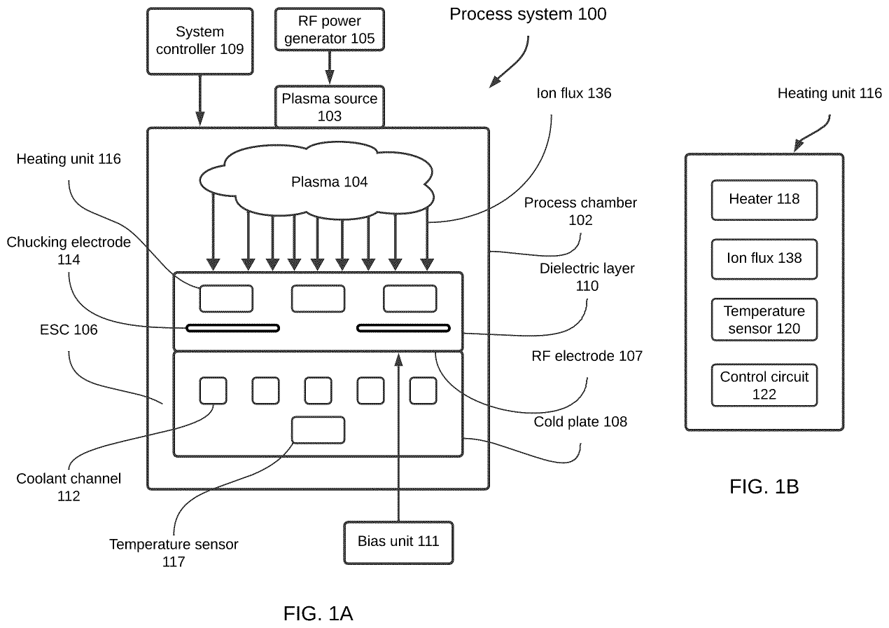

FIG. 1 depicts a schematic diagram of a semiconductor manufacturing process system, denoted as 100. The process system 100 includes a process chamber 102 configured to create a vacuum environment for processing. The process system 100 further comprises a plasma source 103, powered by an RF power generator 105, for generating plasma 104 within the process chamber 102. An ESC 106 is utilized to hold a substrate, such as a semiconductor wafer, during processing.

Precise control of the substrate's temperature during processing is critically important for many processes. The temperature is controlled by balancing the heating and cooling of the ESC 106. A cold plate 108 provides a cooling mechanism by circulating coolant through one or more coolant channels 112. The cold plate 108 is typically made from a piece of metal like aluminum. The cold plate 108 further comprises a temperature sensor 117 for measuring the temperature near the coolant channel 112. The temperature sensor 117 needs to be carefully placed to avoid interference from the coolant flow while ensuring accurate measurements. Multiple sensors may be utilized to measure the temperature distribution in the cold plate 108.

Atop the cold plate 108 is a dielectric layer 110, typically constructed from a material like aluminum nitride. Chuck electrodes 114 are embedded within the dielectric layer 110 to provide electrostatic chucking force to hold the substrate. On the surface of the ESC 106, grooves (not shown in FIG. 1) are utilized to supply high-pressure inert gas flow. Helium is typically used for this function. Stability for the substrate is achieved through a balance between the electrostatic force and the pressure difference between the inert gas layer and the vacuum within the process chamber 102.

In some implementations, the ESC 106 receives RF power from a bias unit 111 via an RF electrode 107, generating a bias voltage for the substrate. The bias voltage is utilized to accelerate ions in the plasma 104, which are essential for high aspect ratio (HAR) etching.

The dielectric layer 110 further includes one or more heating units 116 to heat the surface of the ESC 106. A schematic diagram of the heating unit 116 is shown in FIG. 1B. The heating unit 116 includes a heater 118. The heater 118 may be a resistor or an active device, such as a MOSFET or a bipolar transistor. The heating unit 116 includes ion flux 138 from the plasma 104 as an additional heating source. The heating unit 116 also includes a temperature sensor 120 embedded within the dielectric layer 110 for measuring the temperature of the surface of the ESC 106. Depending on the implementation, the temperature sensor 120 may include diodes, transistors, or resistors. The heating unit 116 further comprises a control circuit 122 for controlling temperature of a defined surface area or a zone of the ESC 106.

The process system 100 operates under the supervision of a system controller 109. During a plasma processing, the ion currents 138 impacting the surface of the ESC may provide additional power to heat the zones of the ESC 106. The bias unit 111 provides a bias voltage to accelerate ions from the plasma 104. Consequently, the heating power required to sustain the targeted zonal temperatures will be reduced. The reduction of the heating power before and after a plasma 104 is ignited is a measurement of the ion currents.

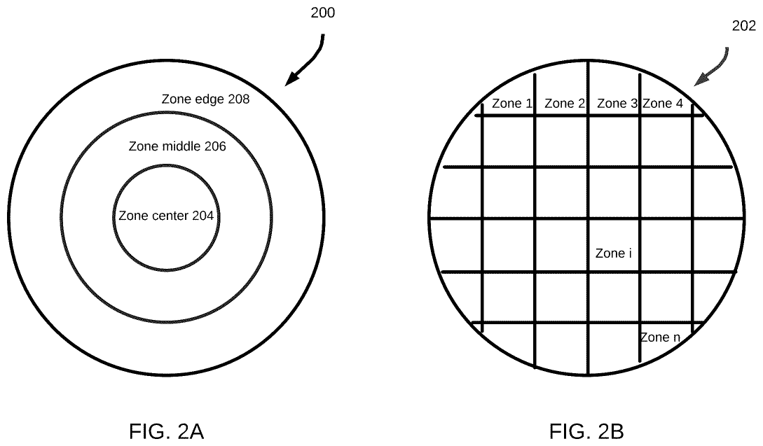

The ESC 106 may include multiple zones for providing distinct temperatures. Referring to FIG. 2A, a top view of one embodiment, denoted as 200, illustrates three concentric zones of the chuck: zone center 204, zone middle 206, and zone edge 208. Each zone is designed to provide an independently controlled temperature. Each zone includes an independent heating unit 116. Each zone may also include one or more temperature sensors 120.

When multiple zones are used, one or more temperature sensors 117 may also be included for the cold plate 108.

FIG. 2B depicts another embodiment, denoted as 202, where the ESC 106 is divided into zones represented by a grid. The zones are labeled as zone 1, zone 2, zone 3, zone 4, . . . , zone i, . . . , and zone n. Each zone provides an independently controlled temperature via an independent heating unit 116. Similarly, additional sensors 117 may be placed within the cold plate 108.

In one implementation, the zones may be thermally isolated. In another implementation, the zones may not be thermally isolated.

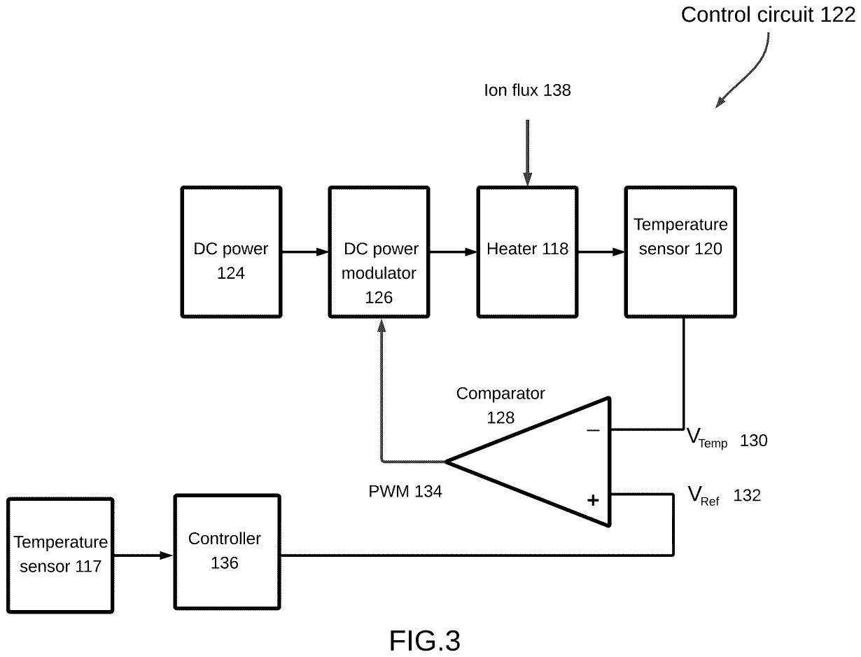

FIG. 3 illustrates an exemplary control circuit 122 based on a thermal feedback loop for controlling surface temperature of the ESC 106. In the embodiment shown in FIG. 3, the control circuit 122 comprises a DC power 124 drawn from a conventional power supply, which may be an AC power source. An AC/DC converter is required to convert the power from AC to DC if the power is derived from the AC power source.

In one aspect of the embodiment, block 126 modulates DC power 124 using a PWM signal 134. In one implementation, the PWM signal includes a squared waveform. The ratio of the on-time to the period of the signal is defined as the duty cycle. The output power of block 126, in PWM form, is utilized by the heater 118. The power received by the heater 118 is a function of the amplitude and duty cycle of the PWM signals. In one implementation, the modulated DC power may also be converted back to the DC power before it is delivered to the heater 118.

It should be noted that in the process chamber 102 with plasma 104, the surface of the ESC 106 can also be affected by ion flux 138, particularly if a high bias voltage is applied to the substrate for accelerating the ions.

The temperature sensor 120 measures the temperature of the dielectric layer 110 near its surface. The temperature sensor 120 outputs a voltage signal. Comparator 128 takes one input from the output of temperature sensor 120, denoted as V_{Temp} 130, and another input from a reference generated by controller 136, denoted as V_{Ref} 132. The output of comparator 128, in PWM form, is coupled to an input of DC power modulator 126 to modulate the DC power 124, completing the thermal feedback loop. The temperature will oscillate around a small value set by the reference voltage. The reference voltage V_{Ref} is determined by the controller 136 or the system controller 109, which may utilize a lookup table or a neural network to infer the reference voltage. The lookup table and the neural network are created during a calibration phase with a first testing procedure to be described.

It should be noted that the power required to sustain the temperature level around which oscillates also depends on other factors, such as the temperature of the cold plate 108. Therefore, the controller 136 or the system controller 109 must generate V_{Ref} by accounting for these factors to control the temperature precisely through a calibration procedure.

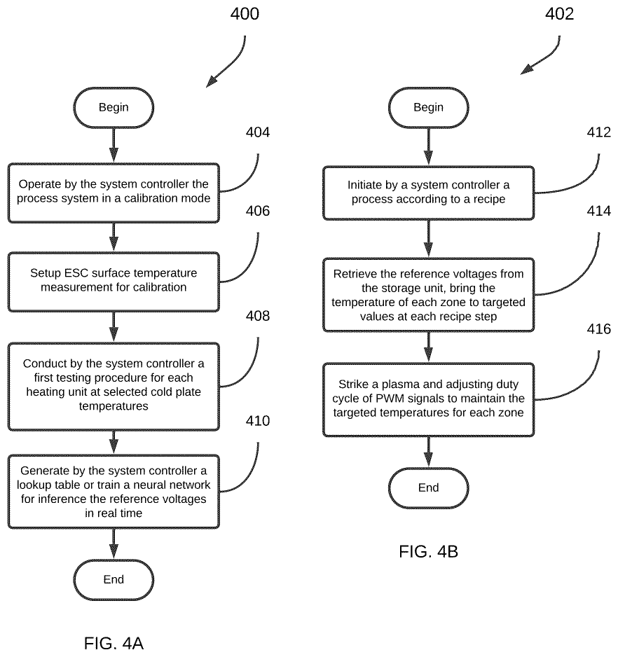

FIG. 4A shows a flowchart for a calibration process to determine reference voltages for the control circuit 122. Process 400 begins with step 404, where the process system operates in calibration mode under the system controller 109. In step 406, a mechanism for measuring ESC surface temperature is set up. In one case, a specially designed apparatus with a shape similar to a wafer is placed on the top of the ESC. The apparatus includes an array of high precision temperature sensors for measuring the surface temperatures across the ESC surface. In step 408, the system controller 109 runs a first testing procedure for each heating unit 116 at selected cold plate temperatures. After completing the test procedure, reference voltages for each heating units for different cold plate temperatures at each zone are determined. In step 410, the generated data is stored in the storage unit of controller 136 or system controller 109. In one implementation, a lookup table is created for deriving the voltage reference in real time based on a recipe. In another implementation, a neural network is trained based on the data. The reference voltages can be determined in real time by operating the neural network in inference mode.

FIG. 4B illustrates a flowchart for controlling the temperature of the zonal ESC. Process 402 begins with step 412, where a process is initiated according to a recipe. In step 414, the lookup table or the neural network data stored in the controller 136 or the system controller 109 is retrieved. The controller 136 or the system controller 109 then generates reference voltages for each heating unit 116 at each recipe step for each ESC zone. Either a lookup table or a neural network is used to infer the appropriate reference voltages based on the cold plate temperatures.

In step 416, plasma 104 is ignited, and the PWM signals are dynamically adjusted by the control circuits to achieve the required zonal temperatures.

This invention provides an effective solution for controlling ESC temperatures. The system and method maintain desired temperatures robustly by dynamically adjusting the PWM signal's duty cycle to mitigate noise or interference. For example, if PWM signals are altered due to electromagnetic fields from RF power generators, the duty cycle is rapidly adjusted to maintain the required temperature.

Additionally, in scenarios where ion flux 138 acts as an additional heating source, the control circuit automatically reduces the power required to maintain the targeted temperature. This adaptive capability ensures precise and efficient temperature regulation across the ESC zones under varying process conditions.

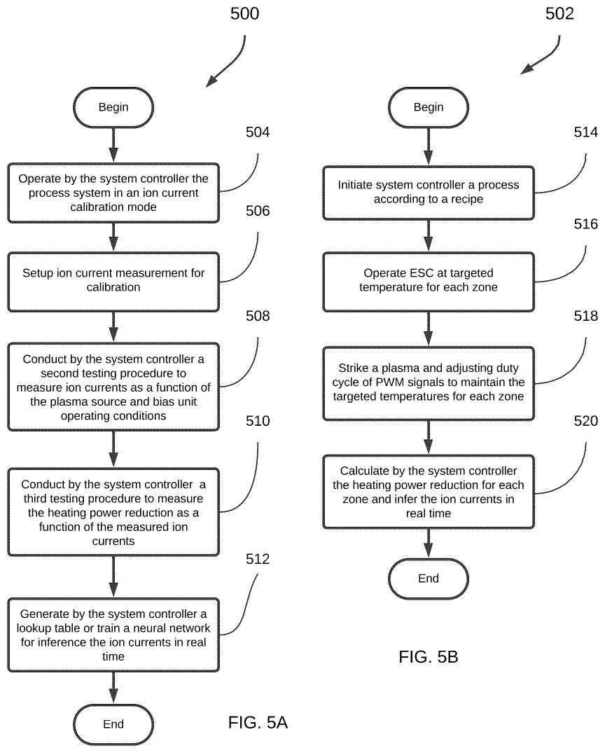

FIG. 5A presents a flowchart detailing a process 500 for calibrating ion currents to the operating conditions of the plasma source 103 and the bias unit 111 of the ESC 106. Process 500 begins with step 504, where the system controller 109 operates the process system 100 in an ion current calibration mode. In step 506, the ion current measurement setup for calibration is initialized.

Several commonly used methods for measuring ion currents in a plasma processing chamber include:
Langmuir Probe: A small electrode inserted into the plasma. By applying a varying voltage to the probe, the current-voltage characteristic is measured, providing information about ion current, electron temperature, and plasma density.
Ion Energy Analyzer (IEA): A device used to measure the energy distribution of ions reaching the chamber walls or substrate. It employs a gridded electrode system to filter ions by energy before measuring their current.
Faraday Cup: A metal cup designed to collect charged particles. Ion current is measured by detecting the charge collected as ions strike the cup's surface, commonly used for beam diagnostics.
Electrode Current Measurement: Ion current is indirectly measured by monitoring the current flowing to electrodes placed atop the ESC during plasma operation. Current sensors or ammeters integrated into the electrode or ground return path are used.
Retarding Field Energy Analyzer (RFEA): Uses a series of grids to filter ions by energy. Ions passing through the grids are collected by an electrode, and ion current is measured as a function of the retarding voltage.

In step 508, the system controller 109 conducts a second testing procedure using one of the aforementioned methods to measure ion currents as a function of the operating conditions of the plasma source 103 and the bias unit 111. These operating conditions are derived from the recipe. The measured ion currents, correlated to the operating conditions, are recorded in the storage unit of the system controller 109.

In step 510, the system controller 109 operates each zone of the ESC 106 at targeted temperatures and records the heating power for each heater. Subsequently, a third testing procedure is conducted by initiating plasma 104 in the chamber under specified operating conditions while ion currents are measured. The system controller 109 records the reductions in heating power at each zone before and after the ignition of the plasma 104, establishing a relationship between reduced power and ion currents under specified conditions, including targeted ESC surface temperatures and cold plate temperatures.

In step 512, the system controller 109 generates a lookup table or trains a neural network based on the data captured in step 510. The lookup table or trained neural network is used to infer in real time ion currents based on heating power reductions.

FIG. 5B showcases a flowchart of a method for determining ion currents during plasma processing based on data from previously conducted during the testing procedures. Process 502 begins with step 514, where the system controller 109 initiates a process according to a recipe. In step 516, the system controller 109 operates the ESC at targeted temperatures for each zone during each recipe step. Heating powers are measured and recorded by the system controller 109.

In step 518, the recipe is executed step by step, with the system controller 109 measuring the duty cycles of the PWM signals and determining the heating powers. In step 520, the system controller 109 calculates the heating power reductions for each zone at each recipe step. The ion currents are then inferred using the lookup table or the neural network, enabling real time determination of ion currents during plasma processing.

Measured heating power reductions across the zones can be used directly to assess the uniformity of ion currents within the plasma processing chamber, simplifying real-time control. In some instances, a control mechanism can be employed to adjust the ion currents and achieve the desired uniformity by configuring the plasma source or the bias unit with tunable knobs.

1. An electrostatic chuck (ESC) of a process system, comprising:
a plurality of zones, each zone including:
a heating unit configured to adjust the temperature of the zone;
a temperature sensor configured to measure the temperature of the zone; and
a cold plate including one or more temperature sensors and coolant channels;
a control circuit of the heating unit, including:
a thermal feedback loop configured to dynamically adjust the power delivered to a heater of the heating unit based on the measured temperature of the zone;
a pulse-width modulation (PWM) mechanism configured to regulate the power delivered to the heater for achieving a targeted temperature for the zone as stipulated in a recipe; and
a system controller configured to conduct a first, second, and third testing procedures,
wherein the first testing procedure is configured to determine reference voltages for the control circuits to achieve the targeted temperature for the zone;
wherein the second testing procedure is configured to determine ion current as a function of the operating conditions of a plasma source and a bias unit of the process system; and
wherein the third testing procedure is configured to determine the ion current as a function of heating power reductions required to sustain the targeted temperature after plasma ignition.

2. The ESC of claim 1, wherein the first, second, and third testing procedures are conducted for each of the zones.

3. The ESC of claim 2, wherein the data generated from the testing procedures are stored in a storage unit of the system controller and organized into lookup tables.

4. The ESC of claim 3, wherein one of the lookup tables is utilized to derive ion currents in real time based on the heating power measured before and after plasma ignition.

5. The ESC of claim 2, wherein the data generated from the testing procedures are utilized to train one or more neural networks.

6. The ESC of claim 5, wherein one of the neural networks is utilized to infer ion currents in real time during processing based on the heating power measured before and after plasma ignition.

7. The ESC of claim 1, wherein the control circuit includes a PWM generator configured to adjust the duty cycle of the power delivered to each heater based on a feedback signal from the temperature sensor.

8. The ESC of claim 7, wherein the control circuit further includes a comparator that compares a reference voltage with the measured temperature signal from the temperature sensor to generate the feedback signal for controlling the power delivered to the heater, wherein the power is modulated as a function of the ion currents.

9. The ESC of claim 1, wherein the controller performs the third testing procedure by measuring ion currents using an ion current measurement apparatus and correlating the measured ion currents with heating power reductions before and after the plasma ignition at targeted zonal temperatures.

10. The ESC of claim 1, wherein the control circuit includes a controller.

11. The ESC of claim 10, wherein the controller is operated under supervision of the system controller.

12. A method for determining ion currents during plasma processing in a process chamber, comprising:
providing an ESC with a plurality of zones, each zone configured with a heating unit including a control circuit;
utilizing a thermal feedback loop of the control circuit to bring each zone into targeted temperature based on a recipe and recording required heating powers;
igniting a plasma according to the recipe; and
measuring and recording reductions in heating power required to sustain the targeted temperatures.

13. The method of claim 12, wherein the measured reductions in heating power are utilized to evaluate the uniformity of the ion currents within the chamber.

14. The method of claim 12, further comprising executing a first testing procedure to determine reference voltages for the control circuits to achieve the targeted temperatures for the zones.

15. The method of claim 14, further comprising executing a second testing procedure to determine ion currents as a function of the operating conditions of a plasma source and a bias unit of the process system.

16. The method of claim 15, wherein the second testing procedure measures ion currents using one or more of Langmuir probes, Faraday cups, or electrode current monitoring.

17. The method of claim 15, further comprising executing a third testing procedure to determine ion currents as a function of heating power reductions required to sustain the targeted temperature before and after plasma ignition.

18. The method of claim 17, further comprising determining values of the ion currents based on measured reductions in heating power by using a lookup table or a neural network.

19. The method of claim 18, wherein the lookup table is generated using data collected during the testing procedures.

20. The method of claim 18, wherein the neural network is trained using data collected during the testing procedures.
